(19) United States
(12) Patent Application Publication
(10) Pub. No.: US 2011/0252853 A1
(43) Pub. Date: Oct. 20, 2011

(54) METHOD AND APPARATUS FOR COMPACTING A CIGS THIN FILM IN A NON-VACUUM ENVIRONMENT

(75) Inventor: Uen-Ren Chen, Taoyuan (TW)

(73) Assignee: JENN FENG NEW ENERGY CO., LTD., Taoyuan (TW)

(21) Appl. No.: 12/761,496

(22) Filed: Apr. 16, 2010

(51) Int. Cl. B21B 1/08; B21B 23/00

(52) U.S. Cl. 72/199; 72/365.2

(57) ABSTRACT

A method and an apparatus for compacting a CIGS thin film in a non-vacuum environment are provided. According to the present invention, a substrate having a CIGS light absorbing layer configured thereon is processed with a soft baking process. Then, a pneumatic cylinder is employed for providing a pressure for driving a roller which is fixed to a holder. The holder is connected to the pneumatic cylinder. The roller is driven to downwardly apply a pressing force onto the CIGS light absorbing layer. The substrate is then moved back and forth to compact the CIGS light absorbing layer uniformly.

### BACKGROUND OF THE INVENTION

1. Field of the Invention

The present invention relates generally to a method and an apparatus for compacting a copper/indium/gallium/selenium (CIGS) thin film, and more particularly, to a method and an apparatus for compacting a CIGS light absorbing layer of a solar cell in a non-vacuum environment.

2. The Prior Arts

Recently, the oil price remains at a high level, and the environmental protection becomes more concerned all over the world. Correspondingly, many countries have put their efforts for developing renewable energies including solar cell technology. Among many kinds of solar cells, the silicon solar cells are featured with higher photoelectric conversion efficiency, and the technology thereof has been well established. However, the further application of the silicon solar cells is very much restricted by the insufficient supply of the raw material, i.e., silicon wafers. Therefore, thin film solar modules are more and more concerned and developed in commercial applications since they only use 1/100 of the raw materials in comparison with crystallized silicon solar cells. Typically, according to raw materials, thin film solar modules can be classified into three categories, including amorphous silicon, CIGS, and cadmium telluride (CdTe). It is well known that the CIGS thin film has the highest photoelectric conversion efficiency among these thin films. For example, a CIGS solar cell had achieved a conversion efficiency up to 20%, and a CIGS thin film solar module had already achieved a conversion efficiency up to 14% during the past two years.

Conventional methods for fabricating CIGS solar cells are typically categorized into vacuum processing and non-vacuum processing. In a vacuum processing, a sputtering process or a co-evaporation process is typically employed. Unfortunately, the vacuum processing requires expansive processing equipment and is featured with a low material utilization. On the contrary, the non-vacuum processing, e.g., printing or electrodeposition process is still remained in the experimental stage, and not yet as mature as to be mass production.

A well-known problem of the non-vacuum processing is that non-compact CIGS thin film is difficult to get larger grains. As a result, too much grain boundaries retard absorbing the sunlight. Accordingly, a CIGS solar cell with non-compact CIGS thin absorbing layer will cause a lower conversion efficiency.

### SUMMARY OF THE INVENTION

A primary objective of the present invention is to provide a method and an apparatus to compact a CIGS thin film in a non-vacuum environment.

According to the present invention, a substrate having a CIGS light absorbing layer configured thereon is processed with a soft baking process. Then, a pneumatic cylinder is designed to drive a roller which is linked to a holder. When the pneumatic cylinder applies a pressing force to the holder, the holder with the roller will press downward onto the CIGS light absorbing layer. The substrate is then moved back and forth to compact the CIGS light absorbing layer uniformly.

In accordance with the present invention, the diameter of the roller and the pressing force applied by the roller must be controlled within specific ranges for achieving a better compacting performance. Preferably, a hard coating layer is coated on an outer surface of the roller for protecting the outer surface of the roller.

### BRIEF DESCRIPTION OF THE DRAWINGS

The present invention will be apparent to those skilled in the art by reading the following detailed description of a preferred embodiment thereof, with reference to the attached drawing, in which:

FIG. 1 is a schematic diagram for illustrating a method and an apparatus to compact a CIGS thin film according to an embodiment of the present invention.

### DETAILED DESCRIPTION OF THE PREFERRED EMBODIMENT

The accompanying drawings are included to provide a further understanding of the invention, and are incorporated in and constitute a part of this specification. The drawing illustrates embodiments of the invention and, together with the description, serves to explain the principles of the invention.

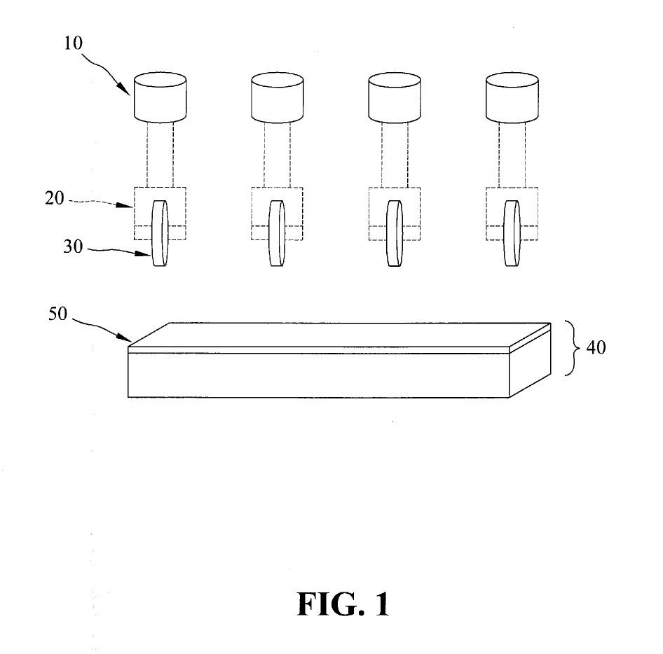

FIG. 1 is a schematic diagram for illustrating a method and an apparatus to compact a CIGS thin film according to an embodiment of the present invention. Referring to FIG. 1, an apparatus was designed to compact a CIGS thin film. The apparatus includes at least one pneumatic cylinder 10, a holder 20, and a roller 30. The holder 20 is connected to the pneumatic cylinder 10. The roller 30 is fixed to the holder 20. The pneumatic cylinder 10 is used to drive downward the holder 20 connected to the pneumatic cylinder 10. The roller 30 fixed to the holder 20 is then pressed onto a substrate 40 beneath the roller 30. As shown in FIG. 1, the substrate 40 includes a CIGS thin film 50 serving as a light absorbing layer coating on an upper surface of the substrate 40. Therefore, the roller 30 presses onto the CIGS thin film 50 to compact the CIGS thin film 50 thereby.

The CIGS thin film 50 is obtained from a deposited CIGS slurry or ink containing CIGS material, and processed with a soft baking process. Such a CIGS thin film has a relatively low densification.

In operation, the pneumatic cylinder 10 is adjusted to provide a suitable air pressure. Then, the pneumatic cylinder 10 drives the holder 20 to downward apply a pressing force on the substrate 40 having the CIGS thin film 50 configured thereon. Then, the substrate 40 is laterally moved forth and back, so that the roller 30 uniformly rolls on the substrate to compact the CIGS thin film 50.

However, it should be noted that the pressure applied by the roller 30 on the CIGS thin film 50 should be controlled within a certain range. If the pressure is too high, the substrate 40 on which the CIGS thin film 50 is configured may be damaged. Preferably, the pressure provided by the pneumatic cylinder is lower than an upper threshold, about 3 kg/cm². Further, on another hand, if the pressure is too low, the holder 20 cannot be driven to rise or fall, and therefore the roller 30 is incapable of applying the pressure onto the CIGS thin film 50. Therefore, the pressure is preferred to be higher than a lower threshold, about 0.2 kg/cm².

Further, the diameter of the roller 30 should be controlled within a suitable range. If the diameter of the roller 30 is too large, the uniformity of compacting performance may decay. If the diameter of the roller 30 is too small, too much rollers 30 have to be used for uniformly compacting the CIGS thin film 50. According to the embodiment of the present invention, the diameter of the roller 30 is preferably controlled in a range of 0.5 cm to 10 cm.

In addition, in order to improve the abrasion resistance of the outer surface of the roller 30, the outer surface of the roller 30 can be processed with a thermal treatment to avoid damaged caused by broken glass. Alternatively, the roller 30 may further include a hard coating layer provided on the outer surface of the roller 30 for protecting the outer surface of the roller 30. The thermal treatment on the outer surface of the roller 30 or the hard coating layer provided on the outer surface of the roller 30 is adapted for avoiding adverse affection caused by sharp stuff or broken chips. Preferably, the hard coating layer is made of electroplated chromium or tungsten. Alternatively, the outer surface of the roller 30 can also be covered with a ceramic material, such as carborundum, diamond like carbon (DLC), or diamond. According to a further aspect of the embodiment, the roller 30 can be made of ceramic. In such a way, the roller 30 with better hardness won't be damaged by any sharp stuff or broken chips.

In summary, the present invention provides a method and an apparatus to compact a CIGS thin film in a non-vacuum environment. According to the present invention, a roller is employed to uniformly roll on the CIGS thin film configured on the substrate for improving the densification of the CIGS thin film, thus providing a solution to a well-known problem as discussed with respect to the conventional technology.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A method for compacting a copper/indium/gallium/selenium (CIGS) thin film in a non-vacuum environment, wherein the CIGS thin film is formed on an upper surface of a substrate serving as a light absorbing layer, the method comprising:
utilizing at least one pneumatic cylinder to apply a pressure in the non-vacuum environment for driving a holder connected to the pneumatic cylinder, wherein the holder drives at least one roller fixed to the holder downward to press on the upper surface of the substrate; and
moving the substrate back and forth to allow the roller uniformly rolling on the CIGS thin film to compact the CIGS thin film,
wherein the CIGS thin film is obtained from a deposited CIGS slurry or ink containing CIGS material, and processed with a soft baking process, wherein the roller is a ceramic roller, or an outer surface of the roller is processed with a thermal treatment to improve a hardness of the outer surface, or the outer surface of the roller is provided with a hard coating layer for protecting the outer surface of the roller.

2. The method according to claim 1, wherein the pressure provided by the pneumatic cylinder is within the range of 0.2 to 3 kg/cm².

3. The method according to claim 1, wherein a diameter of the roller is within the range of 0.5 to 10 cm.

4. The method according to claim 1, wherein the hard coating layer is made of electroplated chromium or tungsten, or the outer surface of the roller is covered with a ceramic material.

5. The method according to claim 4, wherein the ceramic material comprises carborundum, diamond like carbon (DLC), or diamond.

6. An apparatus for compacting a copper/indium/gallium/selenium (CIGS) thin film in a non-vacuum environment, wherein the CIGS thin film is formed on an upper surface of a substrate serving as a light absorbing layer, the apparatus comprising:
at least one pneumatic cylinder adapted for generating a pressure in the non-vacuum environment;
a holder connected to the pneumatic cylinder, wherein the holder is adapted to be driven by the pressure; and
at least one roller is fixed to the holder, wherein the roller is adapted to be driven by the holder downward to press on the upper surface of the substrate.

7. The apparatus according to claim 6, wherein the CIGS thin film is obtained from a deposited CIGS slurry or ink containing CIGS material, and processed with a soft baking process.

8. The apparatus according to claim 6, wherein the roller is a ceramic roller.

9. The apparatus according to claim 6, wherein an outer surface of the roller is processed with a thermal treatment processing for improving a hardness of the outer surface.

10. The apparatus according to claim 6, wherein an outer surface of the roller is provided with a hard coating layer for protecting the outer surface of the roller.

11. The apparatus according to claim 6, wherein the pressure provided by the pneumatic cylinder is within the range of 0.2 to 3 kg/cm².

12. The apparatus according to claim 6, wherein a diameter of the roller is within the range of 0.5 to 10 cm.

13. The apparatus according to claim 10, wherein the hard coating layer is made of electroplated chromium or tungsten.

14. The apparatus according to claim 10, wherein the outer surface of the roller is covered with a ceramic material.

15. The method according to claim 14, wherein the ceramic material comprises carborundum, diamond like carbon (DLC), or diamond.
